(19) United States
(12) Patent Application Publication
(10) Pub. No.: US 2014/0373904 A1
(43) Pub. Date: Dec. 25, 2014

(54) PASTE COMPOSITION FOR SOLAR CELL ELECTRODE AND ELECTRODE PRODUCED THEREFROM

(71) Applicants: Young Wook Choi, Uiwang-si (KR); Dong Jun Kim, Uiwang-si (KR); Eun Kyung Kim, Uiwang-si (KR); Dae Seop Song, Uiwang-si (KR)

(72) Inventors: Young Wook Choi, Uiwang-si (KR); Dong Jun Kim, Uiwang-si (KR); Eun Kyung Kim, Uiwang-si (KR); Dae Seop Song, Uiwang-si (KR)

(21) Appl. No.: 14/362,736

(22) PCT Filed: Mar. 30, 2012
(86) PCT No.: PCT/KR2012/002354

§ 371 Date: Sep. 16, 2014

(30) Foreign Application Priority Data
Dec. 8, 2011 (KR) 10-2011-0131376

(51) Int. Cl. H01L 31/0224; H01B 1/16; H01B 1/22

(52) U.S. Cl. CPC H01L 31/022425; H01B 1/22; H01B 1/16
USPC 136/252; 252/514

(57) ABSTRACT

The present invention relates to a paste composition for a solar cell electrode and an electrode produced therefrom. The present invention relates to a paste composition for a solar cell electrode, and an electrode produced therefrom, the paste composition comprising conductive powders, a glass frit, and an organic vehicle, the glass frit including PbO, SiO₂, and TeO₂, wherein an amount of said TeO₂ included in the glass frit is about 1-20% by weight.

### TECHNICAL FIELD

The present invention relates to a paste composition for solar cell electrodes and an electrode produced therefrom. The present invention relates to a paste composition for solar cell electrodes, which minimizes adverse influence on a p-n junction under high surface resistance while reducing contact resistance, thereby improving solar cell efficiency, and an electrode produced therefrom.

### BACKGROUND ART

Solar cells generate electric energy using the photovoltaic effect of a p-n junction which converts photons of sunlight into electricity. In the solar cell, front and rear electrodes are formed on upper and lower surfaces of a semiconductor wafer or substrate with the p-n junction, respectively. Then, the photovoltaic effect of the p-n junction is induced by sunlight entering the semiconductor wafer and electrons generated by the photovoltaic effect of the p-n junction provide electric current to the outside through the electrodes. The electrodes of the solar cell are formed on the wafer by applying, patterning, and baking a composition for electrodes.

Continuous reduction in emitter thickness for improvement of solar cell efficiency can cause shunting which can deteriorate solar cell performance. In addition, solar cells have been gradually increased in area to achieve high efficiency. In this case, however, there can be a problem of efficiency deterioration due to increase in contact resistance of the solar cell.

Further, with increasing use of wafers having various surface resistances, a temperature range for baking is widened and thus there is an increasing need for electrode pastes capable of securing thermal stability in a wide baking temperature range.

Therefore, there is a need for a paste composition for electrodes capable of securing p-n junction stability while improving solar cell efficiency by minimizing adverse influence on the p-n junction given varying surface resistances.

### DISCLOSURE

### Technical Problem

It is an aspect of the present invention to provide a paste composition for solar cell electrodes capable of minimizing adverse influence on a p-n junction given varying surface resistances.

It is another aspect of the present invention to provide a paste composition for solar cell electrodes, which provides high solar cell efficiency given varying surface resistances.

It is a further aspect of the present invention to provide electrodes fabricated using the paste composition for electrodes.

### Technical Solution

In accordance with one aspect of the invention, a paste composition for solar cell electrodes may include a conductive powder, a glass frit, and an organic vehicle, wherein the glass frit includes PbO, SiO₂ and TeO₂, and TeO₂ is present in an amount of about 1% by weight (wt %) to about 20 wt % in the glass fit.

In one embodiment, PbO may be present in an amount of about 40 wt % to about 80 wt % and SiO₂ may be present in an amount of about 5 wt % to about 20 wt % in the glass frit.

In one embodiment, the glass frit may further include at least one selected from the group consisting of Al₂O₃, ZrO₂, P₂O₅, ZnO, Bi₂O₃, Na₂O, B₂O₃, Ta₂O₅, Fe₂O₃, Cr₂O₃, Co₂O₃, Li₂O, Li₂CO₃, MgO, and MnO₂.

In one embodiment, the glass fit may include about 40 wt % to about 80 wt % of PbO, about 5 wt % to about 20 wt % of SiO₂, about 1 wt % to about 20 wt % of TeO₂, and about 1 wt % to about 20 wt % of B₂O₃.

In one embodiment, the glass fit may include about 40 wt % to about 80 wt % of PbO, about 5 wt % to about 20 wt % of SiO₂, about 1 wt % to about 20 wt % of TeO₂, about 1 wt % to about 10 wt % of Al₂O₃, ZrO2 about 0.1 wt % to about 1 wt %, about 1 wt % to about 10 wt % of ZnO, and about 1 wt % to about 5 wt % of Na₂O.

In one embodiment, the glass frit may have an average particle diameter (D50) of about 0.1 μm to about 5 μm.

In one embodiment, the composition may include about 60 wt % to about 90 wt % of the conductive powder, about 1 wt % to about 10 wt % of the glass fit, and about 7 wt % to about 30 wt % of the organic vehicle.

In accordance with another aspect of the present invention, there is provided an electrode produced using the paste composition for solar cell electrodes.

### Advantageous Effects

The present invention provides a paste composition for solar cell electrodes capable of minimizing adverse influence on a p-n junction given varying surface resistances. The present invention provides a paste composition for solar cell electrodes, which provides high solar cell efficiency even inder various surface resistances.

### DESCRIPTION OF DRAWINGS

FIG. 1 is a schematic view of a solar cell fabricated using a paste composition in accordance with one embodiment of the present invention.

### BEST MODE

In accordance with one aspect of the present invention, a paste composition for solar cell electrodes may include a conductive powder, a glass frit, and an organic vehicle.

In one embodiment, the composition may include about 60 wt % to about 90 wt % of the conductive powder, about 1 wt % to about 10 wt % of the glass frit, and about 7 wt % to about 30 wt % of the organic vehicle.

Conductive Powder

Examples of the conductive powder may include silver (Ag), gold (Au), palladium (Pd), platinum (Pt), copper (Cu), chromium (Cr), cobalt (Co), aluminum (Al), tin (Sn), lead (Pb), zinc (Zn), iron (Fe), iridium (Ir), osmium (Os), rhodium (Rh), tungsten (W), molybdenum (Mo), nickel (Ni), and magnesium (Mg) powder, without being limited thereto. These conductive powders may be used alone or as a mixture or alloy of two or more thereof. Preferably, the conductive powder includes silver powder. In some embodiments, the conductive powder may further include nickel (Ni), cobalt (Co), iron (Fe), zinc (Zn) or copper (Cu) powder in addition to the silver powder.

The conductive powder may have a spherical, flake or amorphous particle shape.

The conductive powder may be a mixture of conductive powders having different particle shapes.

The conductive powder may have an average particle size (D50) of about 0.1 μm to about 3 μm. The average particle size is measured using a Model 1064D particle size analyzer (CILAS Co., Ltd.) after dispersing the conductive powder in isopropyl alcohol (IPA) at 25° C. for 3 minutes via ultrasonication. Within this range of average particle size, the paste composition can provide low contact resistance and line resistance. Preferably, the conductive powder has an average particle size (D50) of about 0.5 μm to about 2 μm.

The conductive powder may be a mixture of conductive particles having different average particle sizes (D50).

The conductive powder may be present in an amount of about 60 wt % to about 90 wt % in the paste. Within this range, the conductive powder may prevent deterioration in conversion efficiency due to resistance increase and difficulty in forming the paste due to relative reduction in amount of the organic vehicle. The conductive powder is preferably present in an amount of about 70 wt % to about 88 wt %, more preferably about 80 wt % to about 85 wt %.

Glass Frit

The glass frit serves to enhance adhesion between the conductive powder and the wafer or the substrate and to form crystal grains of conductive powder in an emitter region by etching an anti-reflection layer and melting the conductive powder so as to reduce contact resistance during a baking process of the electrode paste.

The glass frit may include PbO, SiO₂ and TeO₂. Here, TeO₂ may be present in an amount of about 1 wt % to about 20 wt % in the glass frit. If the amount of TeO₂ is less than 1 wt %, the degree of solidification of Ag by TeO₂ is decreased, thereby causing increase in contact resistance. If the amount of TeO₂ exceeds 20 wt %, reactivity at the silicon interface is deteriorated due to an excess of TeO₂, thereby causing increase in contact resistance. TeO₂ is preferably present in an amount of about about 10 to about 20 wt %, more preferably about 13 wt % to about 19 wt %.

In the glass frit, PbO may be present in an amount of about 40 wt % to about 80 wt %. Within this content range, the paste composition can secure p-n junction stability under various surface resistances and can improve solar cell efficiency. Preferably, PbO is present in an amount of about 50 wt % to about 70 wt %.

In the glass frit, SiO₂ may be present in an amount of about 5 wt % to about 20 wt %. Within this content range, the paste composition can secure p-n junction stability under various surface resistances and can improve solar cell efficiency. Preferably, SiO₂ may be present in an amount of about 5 wt % to about 18 wt %.

In the glass frit, the weight ratio of PbO to TeO₂ (PbO/TeO₂) may range from about 2 to about 6, preferably from about 3 to about 6, more preferably from about 3 to about 5.5.

In the glass frit, the weight ratio of TeO₂ to SiO₂ (TeO₂/SiO₂) may range from about 0.1 to about 3.6, preferably from about 0.8 to about 3.6.

In addition to PbO, SiO₂ and TeO₂, the glass frit may further include at least one selected from the group consisting of Al₂O₃, ZrO₂, P₂O₅, ZnO, Bi₂O₃, Na₂O, B₂O₃, Ta₂O₅, Fe₂O₃, Cr₂O₃, Co₂O₃, Li₂O, Li₂CO₃, MgO, and MnO₂ at a balance amount. The composition of the respective components contained in the glass frit may be adjusted in consideration of efficiency or high temperature stability of the electrode.

In the glass frit, B₂O₃ may be present in an amount of about 1 wt % to about 20 wt %, preferably about 1 wt % to about 10 wt %, more preferably about 1 wt % to about 7 wt %.

In the glass frit, Al₂O₃ may be present in an amount of about 1 wt % to about 10 wt %, preferably about 5 wt % to about 10 wt %.

In the glass frit, ZrO₂ may be present in an amount of about 0.1 wt % to about 1 wt %, preferably about 0.5 wt % to about 1 wt %.

In the glass frit, ZnO may be present in an amount of about 1 wt % to about 10 wt %, preferably about 2 wt % to about 8 wt %.

In the glass fit, Na₂O may be present in an amount of about 1 wt % to about 5 wt %, preferably about 1 wt % to about 3 wt %.

In one embodiment, the glass frit may include PbO, SiO₂, TeO₂, and B₂O₃. Preferably, the glass frit may include about 40 wt % to about 80 wt % of PbO, about 5 wt % to about 20 wt % of SiO₂, about 1 wt % to about 20 wt % of TeO₂, and about 1 wt % to about 20 wt % of B₂O₃.

In another embodiment, the glass frit may include PbO, SiO₂, TeO₂, Al₂O₃, ZrO₂, ZnO, Li₂O, Li₂CO₃, and Na₂O. Preferably, the glass frit may include about 40 wt % to about 80 wt % of PbO, about 5 wt % to about 20 wt % of SiO₂, about 1 wt % to about 20 wt % of TeO₂, about 1 wt % to about 10 wt % of Al₂O₃, about 0.1 wt % to about 1 wt % of ZrO₂, about 1 wt % to about 10 wt % of ZnO, about 1 wt % to about 10 wt % of Li₂O, about 1 wt % to about 10 wt % of Li₂CO₃, and about 1 wt % to about 5 wt % of Na₂O.

In a further embodiment, the glass frit may include PbO, SiO₂, TeO₂, Al₂O₃, ZrO₂, ZnO, and Na₂O. Preferably, the glass frit may include about 40 wt % to about 80 wt % of PbO, 5 wt % to about 20 wt % of about SiO₂, about 1 wt % to about 20 wt % of TeO₂, about 1 wt % to about 10 wt % of about Al₂O₃, about 0.1 wt % to about 1 wt % of ZrO₂, about 1 wt % to about 10 wt % of ZnO, and about 1 wt % to about 5 wt % of Na₂O.

The glass frit may be a crystallized glass frit or a non-crystallized glass frit. Further, the glass frit may be any of leaded glass frits, lead-free glass frits, and mixtures thereof.

The glass frit may be prepared from the aforementioned metal oxides such as PbO, ZnO, and the like through a typical method. For example, the aforementioned components, such as PbO, ZnO, and the like are mixed in the composition range as described above. Mixing may be performed using a ball mill or a planetary mill. The mixed composition is melted at about 900° C. to about 1300° C., followed by quenching to about 25° C. The obtained resultant is subjected to pulverization using a disk mill, a planetary mill, or the like, thereby preparing a glass frit.

The glass frit may have an average particle diameter D50 from about 0.1 μm to about 5 μm, preferably from about 0.5 μm to about 3 μm, more preferably about 2 μm to about 3 μm. The average particle size D50 is measured using a Model 1064LD particle size analyzer (CILAS Co., Ltd.) after dispersing the glass frit in isopropyl alcohol (IPA) at 25° C. for 3 minutes via ultrasonication.

The glass frit may be present in an amount of about 1 wt % to about 10 wt % in the paste composition. Within this content range, it is possible to improve sintering properties and adhesion of the conductive powder while preventing deterioration in conversion efficiency due to resistance increase. Further, it is possible to prevent an excess of the glass frit from remaining after baking, which can cause resistance increase and solderability deterioration. Preferably, the glass frit is present in an amount of about 1 wt % to about 7 wt %, more preferably about 3 wt % to about 7 wt %.

Organic Vehicle

The organic vehicle may include an organic binder which provides liquidity to the paste.

Examples of the organic binder include cellulose polymers, such as ethylcellulose, hydroxyethylcellulose, hydroxypropylcellulose, hydroxyethyl hydroxypropylcellulose, and the like; acrylic copolymers obtained by copolymerization with hydrophilic acrylic monomers such as carboxyl groups; and polyvinyl resins, without being limited thereto. These binders may be may be used alone or as mixtures thereof.

The organic vehicle may further include a solvent. In this case, the organic vehicle may be a solution prepared by dissolving the organic binder in the solvent.

The organic vehicle may include about 5 wt % to about 40 wt % of the organic binder and about 60 wt % to about 95 wt % of the solvent. Preferably, the organic vehicle includes about 6 wt % to about 30 wt % of the organic binder and about 70 wt % to about 94 wt % of the solvent.

The solvent may be an organic solvent having a boiling point of about 120° C. or more. Specifically, the solvent may be selected from the group consisting of carbitol solvents, aliphatic alcohols, ester solvents, cellosolve solvents, and hydrocarbon solvents, which are commonly used in production of electrodes. Examples of the solvents may include butyl carbitol, butyl carbitol acetate, methyl cellosolve, ethyl cellosolve, butyl cellosolve, aliphatic alcohols, terpineol, ethylene glycol, ethylene glycol monobutyl ether, butyl cellosolve acetate, texanol, and mixtures thereof.

The organic vehicle may be present in an amount of about 7 wt % to about 30 wt % in the paste composition. Within this content range, it is possible to prevent inefficient dispersion or excessive increase in viscosity after preparation of the paste composition, which can lead to printing difficulty, and to prevent resistance increase and other problems that can occur during the baking process. Preferably, the organic vehicle is present in an amount of about 10 wt % to about 25 wt %, more preferably about 10 wt % to about 15 wt %.

Optionally, the paste composition may further include typical additives to enhance flow properties, process properties, and stability. The additives may include dispersants, thixotropic agents, plasticizers, viscosity stabilizers, anti-foaming agents, pigments, UV stabilizers, antioxidants, coupling agents, and the like, without being limited thereto. These additives may be used alone or as mixtures thereof These additives may be present in an amount of about 0.1 wt % to about 5 wt % in the paste composition, and this amount may be changed, as needed.

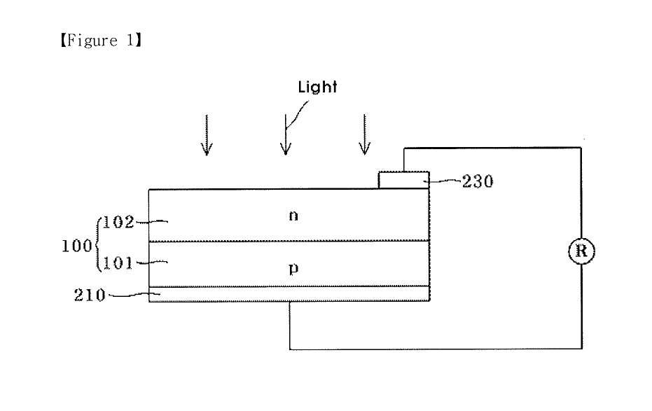

Other aspects of the present invention relate to an electrode produced from the paste composition for solar cell electrodes and a solar cell including the same. FIG. 1 shows a solar cell in accordance with one embodiment of the present invention.

Referring to FIG. 1, a rear electrode 210 and a front electrode 230 may be formed by printing and baking the paste composition on a wafer 100 or substrate that includes a p-layer 101 and an n-layer 102, which will serve as an emitter. For example, a preliminary process for preparing the rear electrode 210 is performed by printing the paste composition on the rear surface of the wafer 100 and drying the printed paste at about 200° C. to about 400° C. for about 10 to about 60 seconds. Further, a preliminary process for preparing the front electrode may be performed by printing the paste on the front surface of the wafer and drying the printed paste. Then, the front electrode and the rear electrode may be formed by baking the wafer at about 400° C. to about 950° C., preferably at about 850° C. to about 950° C., for about 30 to about 50 seconds.

### Mode for Invention

Next, the present invention will be described in more detail with reference to examples. However, it should be understood that these examples are provided for illustration only and are not to be construed in any way as limiting the present invention.

Description of details apparent to those skilled in the art will be omitted.

Details of components used in the following examples and comparative examples are as follows.

As a conductive powder (A), spherical silver powder having an average particle diameter (D50) of 2 μm (Dowa Hightech, AG-4-8) was used. As a glass frit (B), a glass frit prepared from materials selected from among PbO, SiO₂, TeO₂, Al₂O₃, ZrO₂, ZnO, Li₂O, Na₂O and B₂O₃ was used. As organic vehicles (C), ethylcellulose (Dow Chemical, STD4) and butyl carbitol were used.

### EXAMPLES 1-3 AND COMPARATIVE EXAMPLES 1-3

PbO, SiO₂, TeO₂, Al₂O₃, ZrO₂, ZnO, Li₂O, Na₂O and B₂O₃ were mixed in amounts as listed in the following Table 1 (unit: wt %) and melted at 1200° C., followed by quenching to 25° C. The obtained resultant was subjected to pulverization using a disc mill, thereby preparing a glass frit having an average particle diameter (D50) of 2 μm.

To 5 parts by weight of the glass frit prepared as above, 84 parts by weight of the conductive powder and 11 parts by weight of an organic vehicle, which was prepared by adding 1 part by weight of ethylcellulose to 10 parts by weight of butyl carbitol and dissolving at 60° C., followed by mixing and kneading using a 3-roll kneader, thereby preparing a paste composition for solar cell electrodes.

TABLE 1

| | PbO | SiO₂ | TeO₂ | Al₂O₃ | ZrO₂ | ZnO | Li₂O | Na₂O | B₂O₃ |
|---|---|---|---|---|---|---|---|---|---|
| Example 1 | 70 | 10.13 | 13.23 | — | — | — | — | — | 6.64 |
| Example 2 | 70 | 5.13 | 18.23 | — | — | — | — | — | 6.64 |
| Example 3 | 50.25 | 17.34 | 15 | 8.86 | 0.63 | 6.02 | — | 1.9 | — |
| Comparative | 50 | 10.13 | 38.23 | — | — | — | — | — | 1.64 |
| Example 1 | | | | | | | | | |
| Comparative | 80 | 10.13 | 0.5 | — | — | — | — | — | 9.37 |
| Example 2 | | | | | | | | | |
| Comparative | 65.25 | 17.34 | — | 8.86 | 0.63 | 6.02 | 1.78 | 0.12 | — |
| Example 3 | | | | | | | | | |

### Experimental Example: Property Evaluation of Paste Composition and Electrode

Each of the paste compositions prepared in the examples and the comparative examples was deposited on a screen print plate by rolling a scrapper thereon. The paste composition was printed on a monocrystalline wafer having an average surface resistance of 65Ω while squeezing the paste composition to an image area of the screen printing plate. The printed wafer was subjected to baking in a BTU furnace at a 6-zone temperature of 950° C. and a belt speed of 250 rpm. After baking, solar cell efficiency (%) was measured. Results are shown in Table 2.

TABLE 2

| | | | | Comparative | Comparative | Comparative |
|---|---|---|---|---|---|---|
| | Example 1 | Example 2 | Example 3 | Example 1 | Example 2 | Example 3 |
| Efficiency | 17.86 | 16.09 | 16.57 | 3.52 | 15.26 | 14.57 |
| (%) | | | | | | |

As shown in Table 2, the paste compositions of the inventive examples provide high solar cell efficiency. On the contrary, the paste compositions of Comparative Examples 1 to 3 including less than 1 wt % or greater than 20 wt % of TeO₂ provided lower solar cell efficiency than the paste compositions of the inventive examples.

### INDUSTRIAL APPLICABILITY

The present invention provides a paste composition for solar cell electrodes capable of minimizing adverse influence on a p-n junction given varying surface resistances. The present invention provides a paste composition for solar cell electrodes, which provides high solar cell efficiency given varying surface resistances

Although some embodiments have been described above, it will be apparent to those skilled in the art that these embodiments are given by way of illustration only, and that various modifications, changes, alterations, and equivalent embodiments can be made without departing from the spirit and scope of the invention. The scope of the invention should be limited only by the accompanying claims and equivalents thereof.

1. A paste composition for solar cell electrodes, comprising a conductive powder, a glass fit, and an organic vehicle,
wherein the glass frit comprises PbO, SiO₂ and TeO₂, TeO₂ being present in an amount of about 1 wt % to about 20 wt % in the glass fit.

2. The paste composition according to claim 1, wherein PbO is present in an amount of about 40 wt % to about 80 wt % and SiO₂ is present in an amount of about 5 wt % to about 20 wt % in the glass fit.

3. The paste composition according to claim 1, wherein the glass frit further comprises at least one selected from the group consisting of Al₂O₃, ZrO₂, P₂O₅, ZnO, Bi₂O₃, Na₂O, B₂O₃, Ta₂O₅, Fe₂O₃, Cr₂O₃, CO₂O₃, Li₂O, Li₂CO₃, MgO, and MnO₂.

4. The paste composition according to claim 3, wherein the glass fit comprises about 40 wt % to about 80 wt % of PbO, about 5 wt % to about 20 wt % of SiO₂, about 1 wt % to about 20 wt % of TeO₂, and about 1 wt % to about 20 wt % of B₂O₃.

5. The paste composition according to claim 3, wherein the glass fit comprises about 40 wt % to about 80 wt % of PbO, about 5 wt % to about 20 wt % of SiO₂, about 1 wt % to about 20 wt % of TeO₂, about 1 wt % to about 10 wt % of Al₂O₃, about 0.1 wt % to about 1 wt % of ZrO₂, about 1 wt % to about 10 wt % of ZnO, about 1 wt % to about 10 wt % of Li₂O, about 1 wt % to about 10 wt % of Li₂CO₃, and about 1 wt % to about 10 wt % of Na₂O.

6. The paste composition according to claim 3, wherein the glass fit comprises about 40 wt % to about 80 wt % of PbO, about 5 wt % to about 20 wt % of SiO₂, about 1 wt % to about 20 wt % of TeO₂, about 1 wt % to about 10 wt % of Al₂O₃, about 0.1 wt % to about 1 wt % of ZrO₂, about 1 wt % to about 10 wt % of ZnO, and about 1 wt % to about 5 wt % of Na₂O.

7. The paste composition according to claim 1, wherein the glass fit has an average particle diameter (D50) of about 0.1 μm to about 5 μm.

8. The paste composition according to claim 1, wherein the conductive powder comprises at least one selected from the group consisting of silver (Ag), gold (Au), palladium (Pd), platinum (Pt), copper (Cu), chromium (Cr), cobalt (Co), aluminum (Al), tin (Sn), lead (Pb), zinc (Zn), iron (Fe), iridium (Ir), osmium (Os), rhodium (Rh), tungsten (W), molybdenum (Mo), nickel (Ni), and indium tin oxide (ITO).

9. The paste composition according to claim 1, wherein the composition comprises about 60 wt % to about 90 wt % of the conductive powder, about 1 wt % to about 10 wt % of the glass frit, and about 7 wt % to about 30 wt % of the organic vehicle.

10. The paste composition according to claim 1, further comprising: an additive selected from the group consisting of dispersants, thixotropic agents, plasticizers, viscosity stabilizers, anti-foaming agents, pigments, UV stabilizers, antioxidants, and coupling agents.

11. An electrode produced from the paste composition for solar cell electrodes according to claim 1.
